(19) United States
(12) Patent Application Publication
(10) Pub. No.: US 2012/0313655 A1
(43) Pub. Date: Dec. 13, 2012

(54) ELECTRICAL TEST EQUIPMENT HAVING SWITCHABLE INTERMEDIATE-VOLTAGE LINE- LEAKAGE AND RUN TEST POWER SOURCE

(75) Inventors: Roger BALD, Round Lake Beach, IL (US); Yaho Hsieh, Keelung (TW)

(73) Assignee: ASSOCIATED RESEARCH, INC., Lake Forest, IL (US)

(21) Appl. No.: 13/157,450

(22) Filed: Jun. 10, 2011

(51) Int. Cl. G01R 31/00

(52) U.S. Cl. 324/750.01

(57) ABSTRACT

An electrical test instrument includes a built-in, switchable intermediate-voltage power source that enables line-leakage and run testing to be carried-out under higher-than-normal DUT operating voltages.

### BACKGROUND OF THE INVENTION

1. Field of the Invention

The present invention relates to an electrical test instrument, and in particular to an electrical test instrument having a built-in intermediate-voltage power source that enables enhanced run and line leakage testing to be performed at higher-than-normal operating voltages.

The invention may be applied to the multiple function test instruments manufactured by Associated Research, Inc. under the name OMNIA™ and/or to multiple function test instruments of the type described in Associated Research's U.S. Pat. Nos. 6,011,398, 6,515,484, 6,538,420, 6,744,259, 7,026,822, and 7,330,342. However, the principles of the invention are not limited to OMNIA™ test equipment or to multiple function test instruments of the type described in the cited patents, but rather are intended to apply to any electrical test equipment that performs run and/or line leakage testing.

2. Description of Related Art

The OMNIA® line of electrical test instruments sold by Associated Research, Inc., and covered by a number of different patents, are capable of performing a wide variety of electrical tests, including run and line leakage tests as well as high voltage dielectric withstand, insulation resistance, ground bond, and continuity tests, with the tests being selected through a single, user friendly, menu-based interface. The present invention modifies these test instruments by adding an intermediate voltage internal power supply circuit, in order to provide enhanced run and line leakage test capabilities.

The basic principles behind run testing and line leakage testing are respectively disclosed in Associated Research's U.S. Pat. Nos. 6,538,420 and 6,054,865. Line leakage safety compliance testing is primarily used during development of a product to verify whether a design is safe, by simulating possible problems that could occur if the product is faulted or misused while the product is operating under high line conditions (110% of the highest input voltage rating of the product). This is accomplished by plugging the device under test (DUT) into an external source of AC power, touching a probe to the device, and measuring the current present in various human equivalent circuits designed to match the electrical characteristics of a human body) connected between the probe and a reference. Run testing, in contrast, is carried out after final safety testing so that manufacturers can verify the functionality of their products, and to gather basic test data on the products. A run test system ideally allows the product to be powered up immediately after other safety tests are completed in order to measure electrical performance of the device, including amperage, voltage, watts, and power factor, when normal line power is applied to the device being tested.

The present invention adds a variation of the conventional line leakage and run tests to the conventional LLT and run test designs. The variation is to provide the option of carrying out the line leakage or run tests at an intermediate or higher-than-normal voltage. In particular, the invention provides a switchable AC power source that can supply higher than normal operating voltages to the DUT, through the DUT's own power input, for both line leakage and run testing. This is not the same as simply providing a 110V AC or 110V/220V outlet in the casing of a run test instrument, or of providing high voltage ports for dielectric withstand testing. The former does not provide intermediate voltage LLT or run test capabilities, or provide for switching between the high voltages, while the latter does not supply power to the DUT's operating power input (usually a two or three prong electrical plug).

By adding multiple intermediate voltage line leakage and run testing options, the test instrument of the invention gives the user the option of performing line leakage and run tests at higher voltages, without the need for a separate power supply. The added power supply can easily be implemented by modifying an existing run/line leakage test instrument, without changing the basic test instrument user interface or procedures.

### SUMMARY OF THE INVENTION

It is accordingly a first objective of the invention to provide a product testing system that allows enhanced run tests and line leakage tests to be performed using a built-in intermediate voltage power supply.

It is a second objective of the invention to provide an electrical test instrument that is capable of accurately measuring leakage current from the enclosure of the product being tested to the neutral of the input power (line leakage testing), and of measuring input voltage, amperage, power, and power factor of a product (run testing), at higher than line voltage using a built-in switchable intermediate voltage power supply.

These objectives are achieved, in accordance with the principles of a preferred embodiment of the invention, by providing an electrical test instrument having electrical circuitry for converting a conventional line input voltage into at least two intermediate voltages, and for supplying the intermediate voltages to operating voltage outputs configured to receive the operating voltage input of the DUT, for example through a conventional electrical plug and socket arrangement. According to this preferred embodiment, the line input voltage is amplified and supplied to a transformer arranged to output a first intermediate voltage on two secondary windings. The secondary windings are selectively connected in series and parallel between the transformer and the operating voltage outputs to supply the first intermediate voltage and an second intermediate voltage to the intermediate voltage outputs.

The term “intermediate voltage” covers a range of voltages that may be higher or lower than line operating voltages, but that still permit operation of the device. In the preferred embodiments, which are based on U.S. conventional line voltage of 115V AC, the intermediate voltages are variable from 0V to 150V or 0V to 300V. These voltages may be increased for DUTs having 240V operating voltages used outside of North America.

In the preferred embodiments of the invention, the voltage amplification circuitry may further include such enhancements as power factor control, which may be applied not only to the operating voltage outputs but also to other voltage output ports of the test instrument, including dielectric withstand, ground bond, and continuity test ports.

Advantageously, the intermediate voltage power supply shares power conditioning and amplification circuitry with the continuity and ground bond current sources, as well as higher voltage dielectric withstand circuits of the multiple function tester, thereby avoiding redundancy and reducing costs. According to the principles of the preferred embodiment, the input line voltage is conditioned and amplified before supplied not only to the intermediate voltage transformer but also to a high voltage transformer for use in dielectric withstand testing, as well as to additional step down transformers for supplying low voltage continuity test currents. Ground bond currents may be supplied by additional secondary windings of the intermediate voltage transformer.

As noted above, while the preferred embodiment of the invention involves an OMNIA® type multifunction tester, the principle of including intermediate-voltage operating current outlets may be applied to any electrical equipment capable of carrying out line leakage and/or run tests.

### BRIEF DESCRIPTION OF THE DRAWINGS

FIG. 1 is a block diagram showing the general layout of a multiple function electrical tester that includes intermediate-voltage line outputs according to the principles of a preferred embodiment of the invention.

FIGS. 2-6 are schematic circuit diagrams of a power conditioning and amplification board for the multiple function electrical tester of FIG. 1.

FIG. 7 is a schematic circuit diagram showing connections to intermediate-voltage line outputs on a matrix switching board used in the multiple function electrical tester of FIG. 1.

FIG. 8 is a block diagram showing principal power connections to a line leakage test board included in the multiple function electrical tester of FIG. 1.

FIG. 9 is a schematic circuit diagram showing details of the line leakage test board of FIG. 8.

### DETAILED DESCRIPTION OF THE PREFERRED EMBODIMENTS

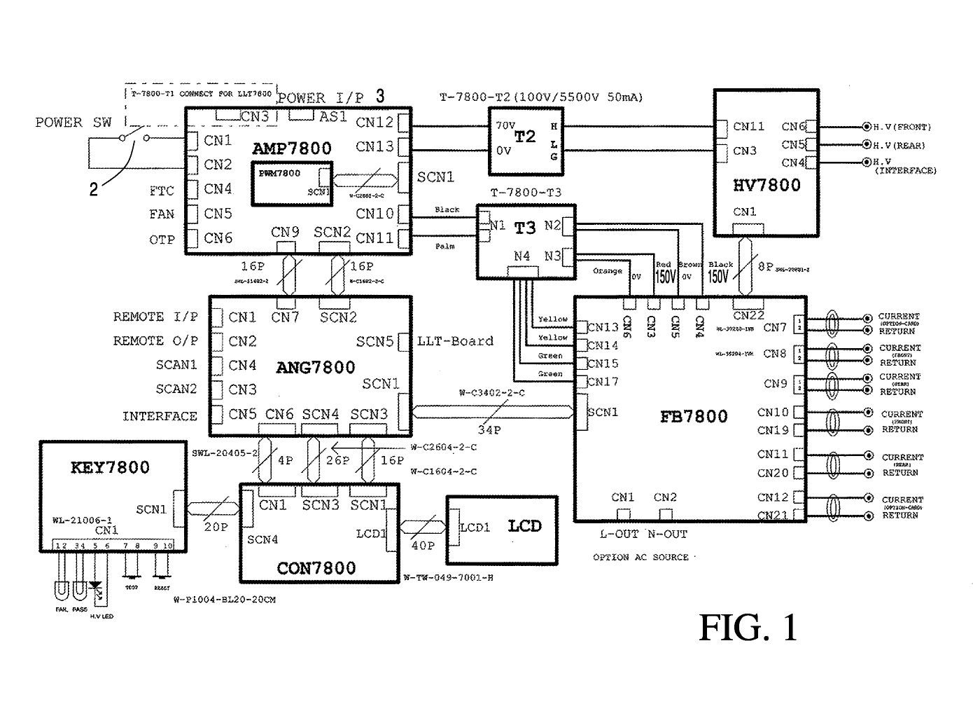

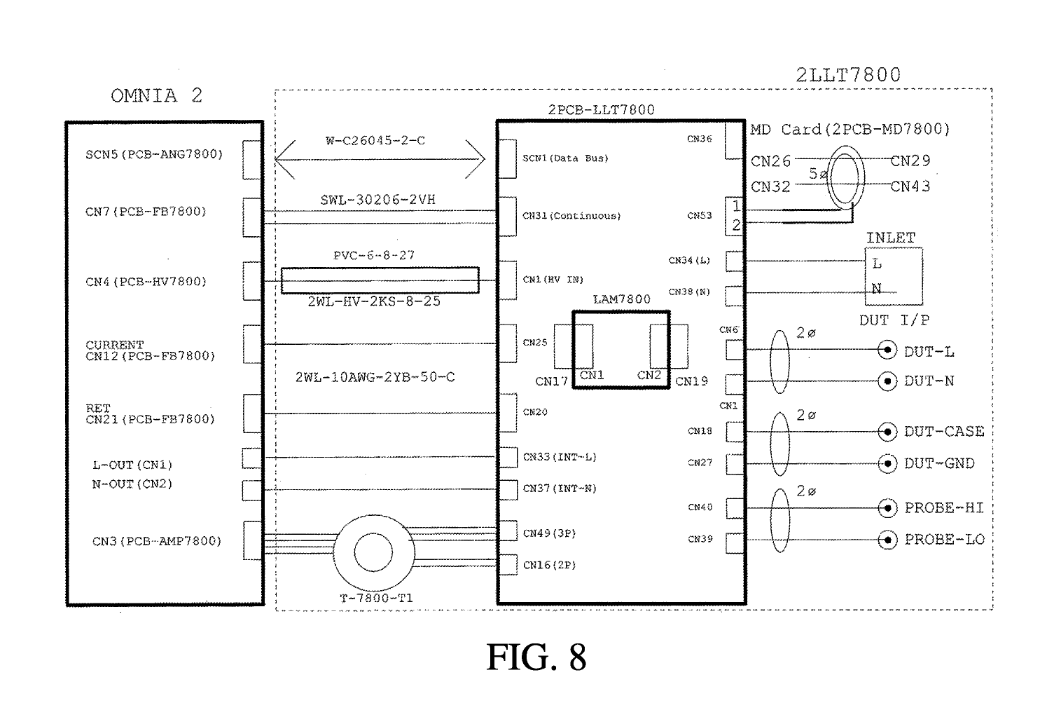

The overall layout of a preferred embodiment of the test equipment of the present invention is illustrated in FIGS. 1 and 8. As shown in FIGS. 1 and 8, the test instrument includes a plurality of “boards,” although those skilled in the art will appreciate that the “boards” illustrated in FIG. 1 need not necessarily be discrete circuit boards. Instead, the boards may be considered to be functional units, which may alternatively be implemented as circuitry on one board or any convenient number of boards, units, or modules. In addition, the arrangement of the circuitry on each of the boards described herein may be varied without departing from the scope of the invention, including elimination of individual circuits or components. For example, various test functions, such as continuity, ground bond, or dielectric withstand, or scanning functions, may be eliminated. Also, the invention is not to be limited to particular display or operator interface types, but rather may utilize any display and interface that permits run test functions to be carried out.

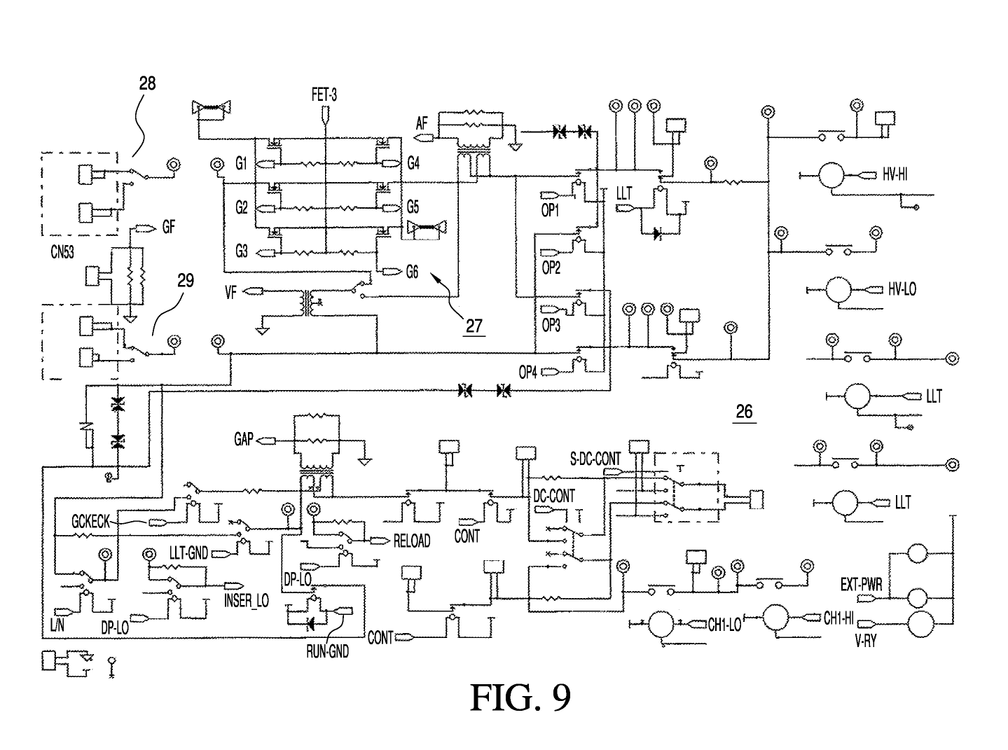

According to the preferred embodiment of the invention, the intermediate voltage power supply is provided by three of the illustrated boards or functional units: main power conditioning and amplification board AMP7800, transformer T3, and switching matrix board FB7800, which convert a conventional AC input, such as a 115V AC input on main power conditioning and amplification board AMP7800, into intermediate voltage AC power, for example switchable 150V AC and 300V AC, for output to a DUT via line and neutral outputs L-OUT and N-OUT on the switching matrix board FB7800. Line and neutral outputs L-OUT and N-OUT are preferably in the form of, or connected to, a conventional socket connector that is arranged to receive the power chord of the DUT can be plugged to supply operating power to the DUT during a run or line leakage test. As illustrated in FIGS. 8 and 9, the line and neutral outputs are actually connected to the socket connector on the casing of the multiple function test instrument via the LLT board shown in FIGS. 8 and 9 so as to enable testing of single fault conditions other than normal line conditions, such as open-neutral, reversed-line, and open-ground conditions, although for run testing purposes a direct connection is also possible.

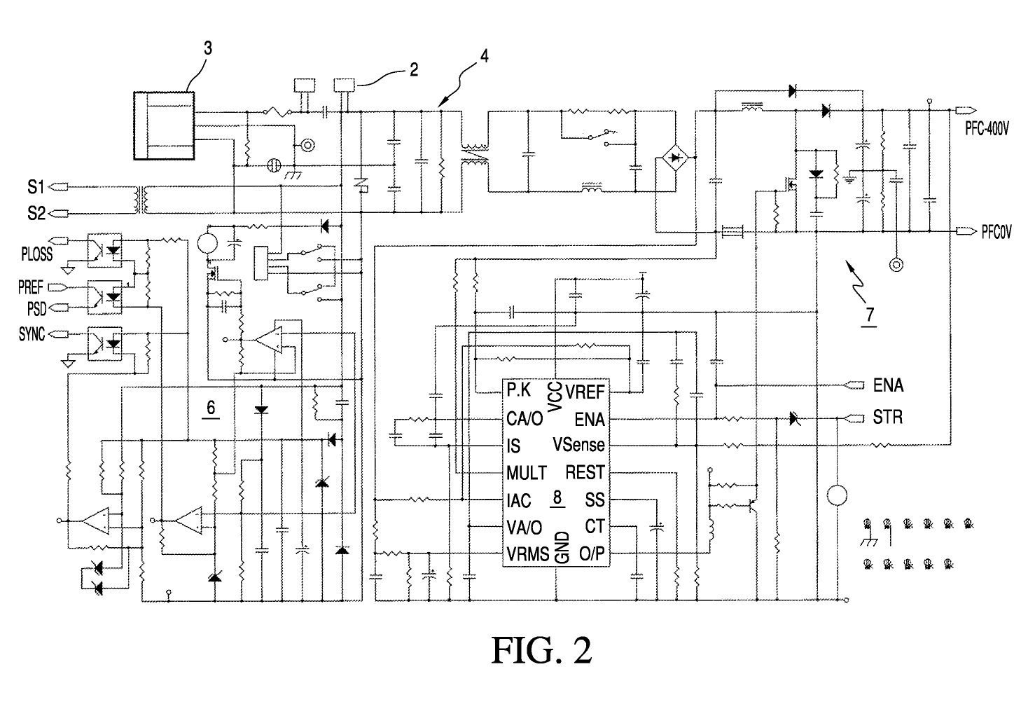

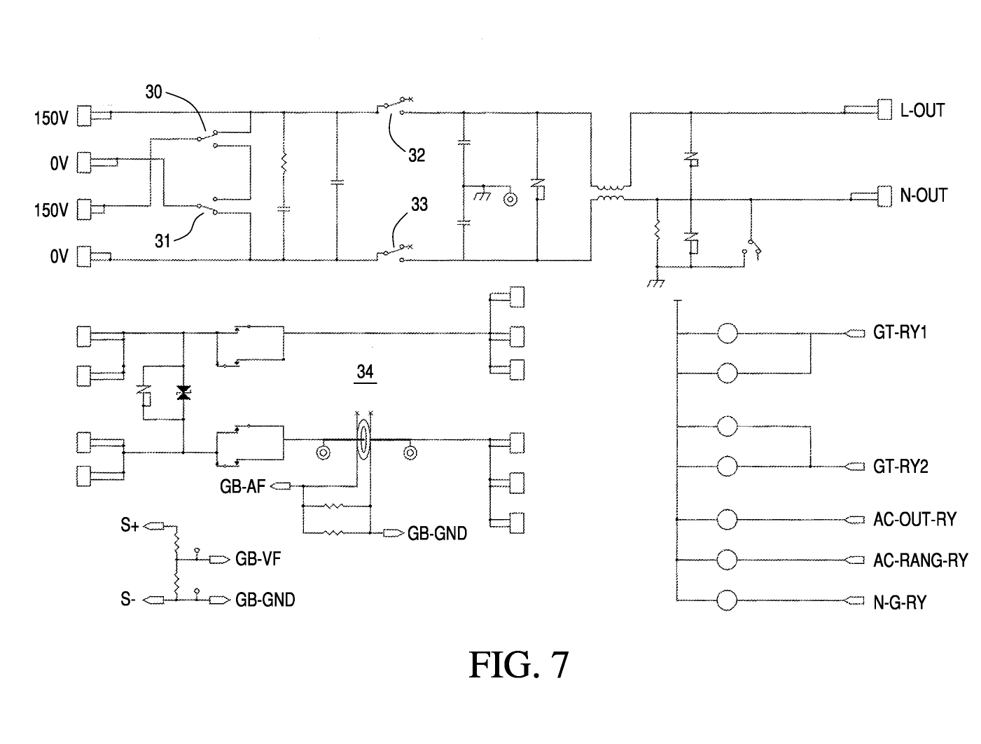

In the illustrated embodiment, as will be described in more detail below, main power conditioning and amplification board AMP7800 converts the line voltage input (115V AC) into a voltage-regulated and power-factor-controlled 400V AC output, utilizing circuitry illustrated in more detail in FIGS. 2-6. The 400V AC output is supplied to transformer T3, which in turns supplies a 150V AC output to various input ports on the switching matrix board FB7800. The 150V AC input to the switching matrix board FB7800, as described in more detail below in connection with FIG. 7, is then switchably combined in series or parallel to provide AC power having variable voltages of 0-150V or 0-300V to the intermediate voltage line and neutral output ports L-OUT and N-OUT and thereby supply a higher than normal operating voltage for line leakage or run testing.

By arranging the boards or units in the illustrated manner, the intermediate voltage power supply can share power conditioning and amplification circuitry with, for example, continuity, ground bond, and high voltage dielectric withstand circuits of the multiple function tester, thereby avoiding redundancy and reducing costs. According to the principles of the preferred embodiment, the 400V AC output of main power supply and amplification board AMP7800 is supplied not only to high voltage dielectric withstand test circuits and to ground bond or continuity test circuits, as in a conventional multiple function tester, but also to the transformer T3 that provides the 150V AC outputs for line leakage and run testing. In the preferred embodiment, the line and neutral intermediate voltage outputs are included on the switching matrix board, but it will be appreciated that they could be included on any of the other illustrated boards, or on a separate board.

In addition to the above-mentioned power conditioning and amplification board AMP7800 and the switching matrix board FB7800, FIG. 1 shows a main control board ANG7800, keypad board KEY7800, an LCD board LCD, an interface board CON7800, a high voltage transformer T2, and a high voltage output board HV7800. The main control board ANG7800 includes a microprocessor and memory circuits, and is connected by busses or jumper cables to the various interface and power control boards so as to provide control signals thereto in response to operator commands and input from test circuitry. Operator input and display functions are provided by the keypad board KEY7800 and interface board CON7800, while LCD drivers for an LCD display are provided on a separate LCD control board LCD. In addition to supplying power to the matrix switching board FB7800 and high voltage board via HV7800 via transformers T3 and T2, the power conditioning and amplification board AMP7800 supplies low internal operating voltages to the main control board ANG7800 and each of the other boards. LLT test circuitry, described below, is provided on board LLT7800, shown only in FIGS. 8 and 9 and connected to the main circuit board by at port SCN5.

Boards ANG7800, KEY7800, CON7800, LCD, and HV7800 are conventional and form no part of the present invention, and therefore will not be described in detail herein. Furthermore, the present invention does not concern details of the operator interface controlled by boards KEY7800, CON7800, and LCD. Those skilled in the art will appreciate that the test and power circuitry described herein may be used with a variety of operator interface configurations, including not only the one provided in the above-mentioned OMNIA™ tester and described in U.S. Pat. No. 6,515,484, but also any other programmable or non-programmable interface.

Turning to FIG. 2, the power conditioning and amplification board AMP7800 includes main power switch 2, which may be controlled to supply power from a conventional line voltage power source input 3 such as a three-prong wall socket. The 115 VAC input power is supplied to fuse F1 and current-limiting input protection circuits 4. The 115V AC power is the supplied to a cable connector 5, reference voltage and sync circuitry 6, and rectifier 7. Cable connector 5 supplies two or three phase line voltages via transformer T1 to the line leakage test board LLT7800, as illustrated in FIG. 8 (for normal line voltage testing as well as to, for example, operate a fan). Reference voltage and sync circuits 6 provide feedback to a power factor controlled voltage/current amplifier circuit 8 in order to amplify the output of rectifier circuit 7 to, in the illustrated embodiment, 400V AC.

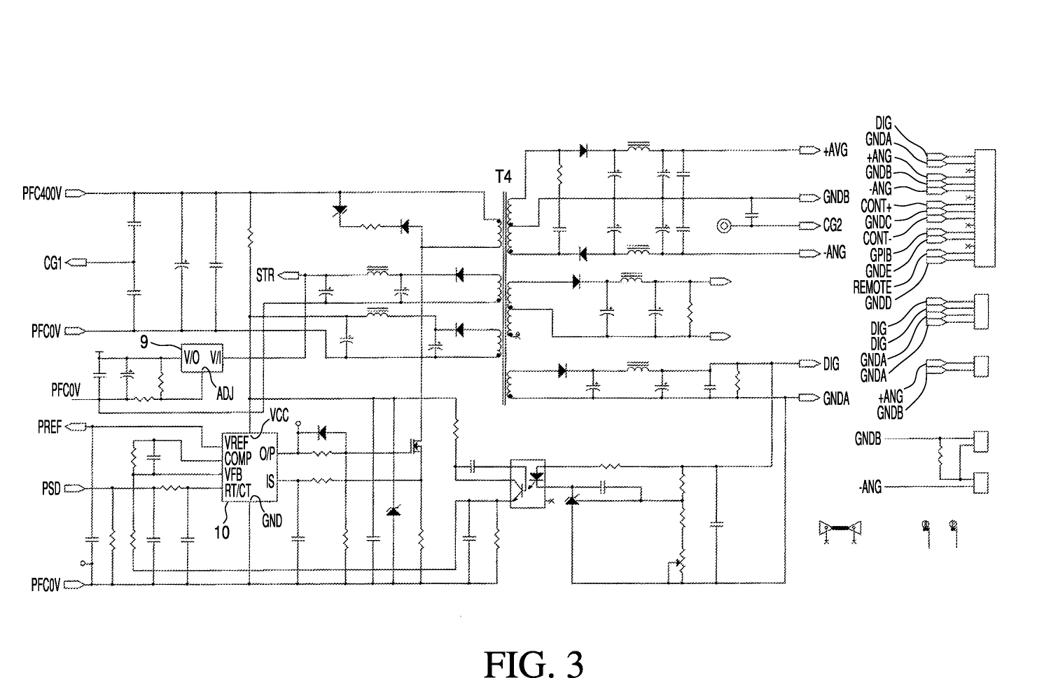

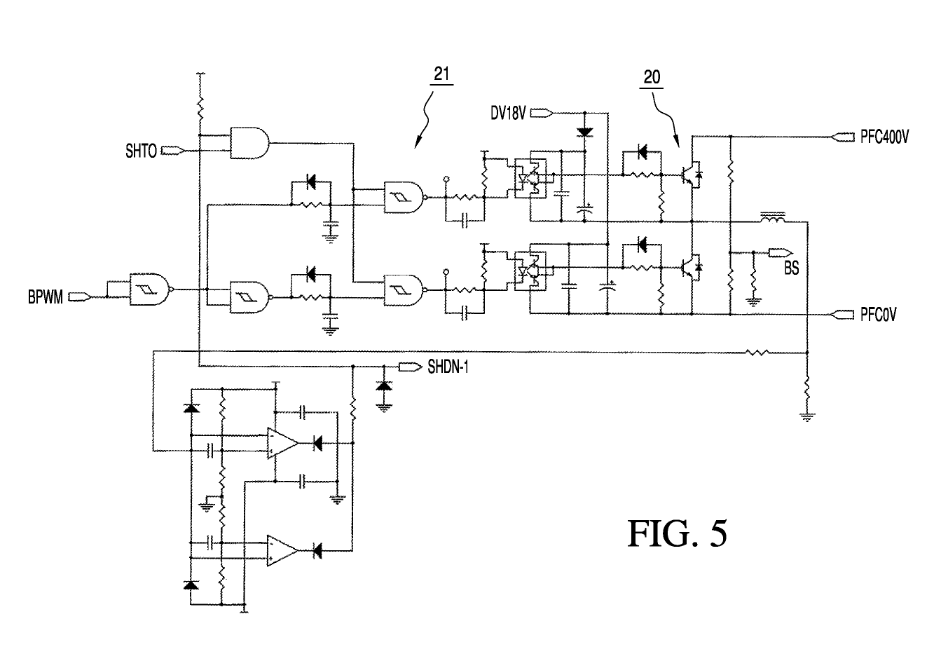

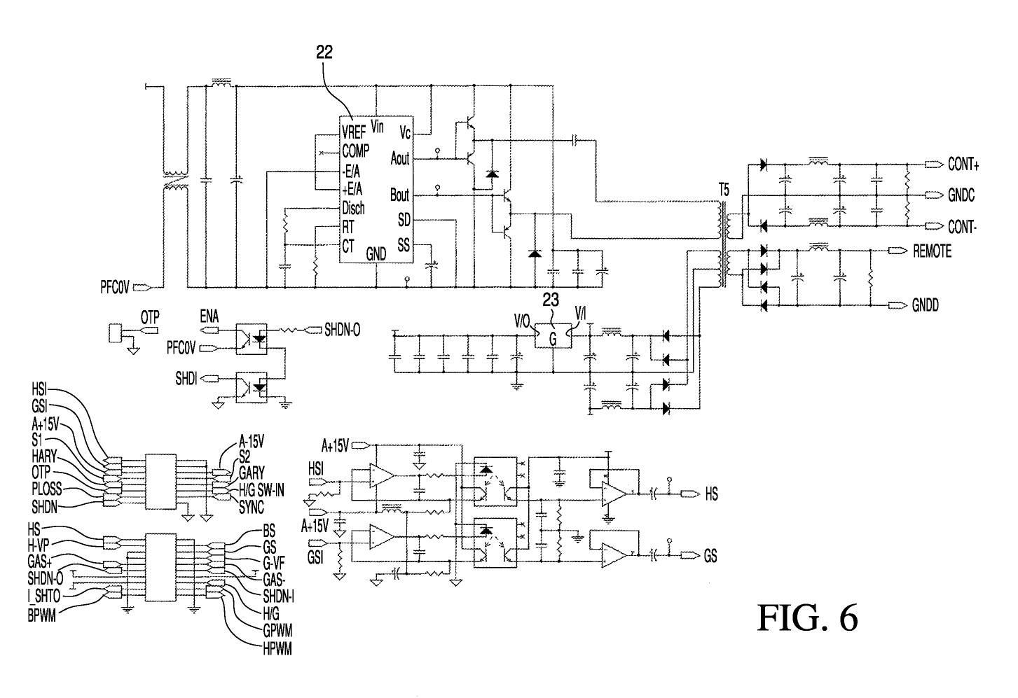

FIGS. 3, 5, and 6 show low voltage generating power circuits for supplying continuity test currents, as well as internal operating voltages, to the main circuit board ANG 7800 via connectors CN4, CN5, CN7, CN8, and CN9 (FIG. 3) and SCN2 (FIGS. 5 and 6). As shown in FIG. 3, the reference voltage and feedback circuits 6 of FIG. 2 supply reference and sync signals to the power regulating circuitry shown in FIG. 3, including voltage regulating integrated circuit 9 and pulse width modulation (PWM) controller 10, which condition the 400V AC waveform output of the power factor controlled amplifier circuit 8 for supply to step down transformer T4. FIGS. 5 and 6 show additional low voltage circuits supplied by an additional step down transformer T5 (FIG. 6) supplied with power, as shown in FIG. 5, through power switches 20 controlled by control signal inputs via latch circuits in the form of Quad 2-input NAND Schmitt triggers 21 and, as shown in FIG. 6, voltage control circuits including pulse width modulator 22 and voltage regulator chip 23. Since the low voltage circuits are not part of the present invention (except insofar as they share with the intermediate voltage circuitry the 400V AC output of amplifier 8), these circuits will not be described in further detail herein.

Those skilled in the art will appreciate that the chip numbers of the various integrated circuits included in FIGS. 2 and 3, such as UC3854AN for amplifier 8, LM317 for voltage regulator 9, and UC3845 for PWM controller 10, are not intended to be limiting and that other amplifier, voltage regulator, and PWM circuitry, including analog as well as digital circuitry, may be substituted for the illustrated circuits/components.

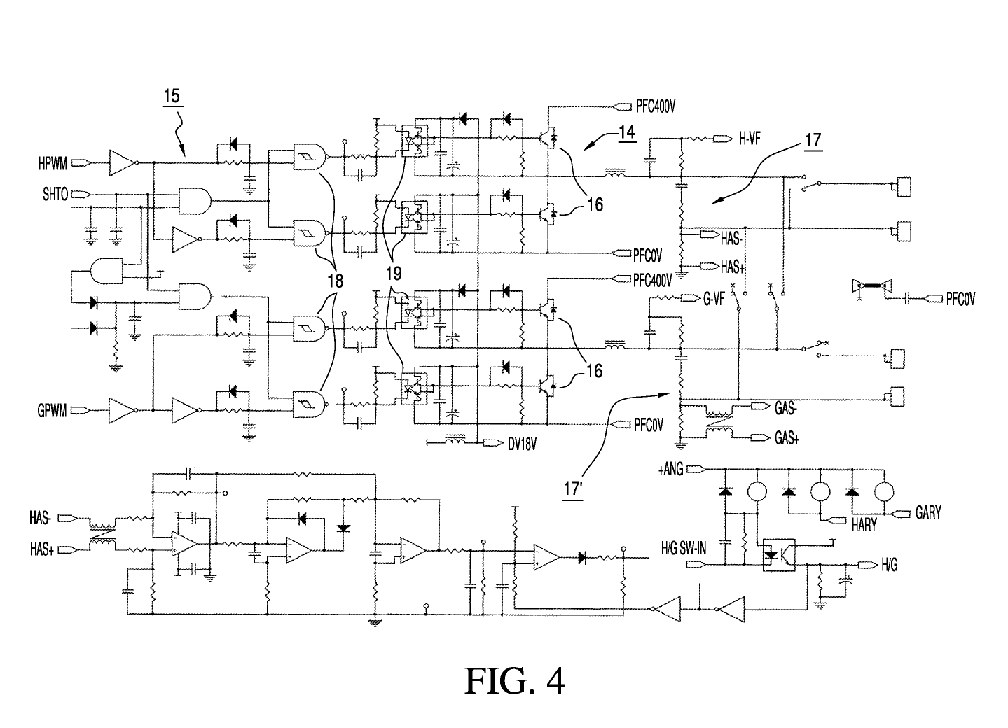

Finally, as shown in FIG. 4, the 400V output of the amplifier circuit 8 is also supplied to power switching circuit 14 for selective distribution to high voltage transformer T2 and intermediate voltage transformer T3, under control of logic circuit 15 controlled signals from a controller (not shown) on main control board ANG7800. Switching circuit 14 is illustrated as including a plurality of power transistors 16 and amplifier output filters 17 and 17′, while logic circuit 15 is illustrated as controlling the power transistors through a plurality of latches in the form of Schmitt triggers 18, and optical isolators 19. It will be appreciated by those skilled in the art that numerous alternative power switching circuits may be substituted for the illustrated circuit.

If high voltage testing is selected, the power-switching circuitry 14 supplies the power to filter 17, which supplies a 70V output to transformer T2 via connectors CN12 and CN13 and from there to a high voltage control board HV7800, details of which form no part of the present invention. A high voltage control board is disclosed in U.S. Pat. No. 6,054,865.

If run or line leakage testing is selected, then a second filter 17′ supplies a variable 0-150V output to transformer T3 via connectors CN11 and CN12. Transformer T3 distributes the variable 0-150V power to connectors CN4 and to CN6 of switching matrix board FB7800 for supply to intermediate voltage outlet ports L-OUT and N-OUT. Outlet ports L-OUT and N-OUT are connected to the LLT board LLT7800, shown in FIGS. 8 and 9, which supplies the intermediate voltage power to a DUT power chord or plug-receiving connector or socket on the casing of the test instrument.

In addition, as shown in FIG. 1, transformer T3 supplies power to conventional ground bond test current and return ports on the casing of the multiple function test instrument via an output terminal of the transformer T3, input ports CN13-CN17 of switching matrix board FB7800, and current/return ports CN7-CN12 and CN19-CN21 on switching matrix board FB7800 (the latter including current monitoring circuitry). Unlike the intermediate voltage power supply circuitry, the current/return power circuitry of switching matrix board FB7800 forms no part of the present invention, and may be similar, equivalent, or identical to that disclosed in U.S. Pat. No. 6,054,865.

As illustrated in FIG. 1, the 150V inputs to the switching matrix board FB7800 are supplied by secondary windings N2 and N3 of the transformer T3, which are connected to intermediate voltage input connectors CN3-CN4 on the switching matrix board. As shown in FIG. 7, the intermediate voltage input connectors CN3-CN6 are connected to the line and neutral ports L-OUT and N-OUT by a switching circuit made up of relays 30, 31, 32, and 33, which permit the input connectors CN3-CN6 to be connected in series or parallel to the output ports L-OUT and L-IN. As a result, either 150V or 300V can be selectively supplied to the output ports, and therefore to the DUT, for both run and line leakage tests.

The connections between ports L-OUT and N-OUT on the matrix switching board FB7800 and corresponding ports DUT-L and DUT-N on the line leakage test board LLT7800, as well as the line leakage test circuitry included on board LLT7800, may be conventional, except that the operating current supplied to the DUT, via the output ports on the line leakage test board LLT7800 and a corresponding socket connector on the casing of the test instrument, is a higher-than-normal 150V or 300V.

Transformer T3 also supplies ground bond currents to the switching matrix board FB7800 via secondary N4 shown in FIG. 1 and connectors CN13, CN14, CN15, and CN17 shown in FIG. 7. These currents are supplied to respective current and return ports through circuit 34 and a conventional switching matrix, details of which are not shown herein but may be similar to that disclosed in Associated Research's U.S. Pat. No. 6,054,865.

As shown in FIGS. 8 and 9, the LLT card LLT7800 receives control signals from the main circuit board ANG7800 via a data bus connected to connector SCN1, high voltages from high voltage board HV7800 via connector CN1, line voltage from the power conditioning and amplifier board AMP7800 (discussed in detail above) via connectors CN16 and CN49, continuity test currents and ground bond current and return outputs from the matrix switching board FB7800 via connectors CN31, CN25, and CN20. The intermediate voltage operating currents are supplied from ports L-OUT and N-OUT on the matrix switching board FB7800 to connectors CN33 and CN37. In addition, the LLT card includes switches 28 and 29 for switching between line and neutral ports CN34 and CN38 connected to the internal power source of the test instrument, and line and neutral ports CN35 and CN38 connected to an external power source, and a current sensor input connector CN53. In addition to DUT line and neutral operating current output ports DUT-L and DUT-N, connections between the LLT board LLT7800 and the DUT include test connections CN18 and CN27 to the case and chassis/ground of the DUT, and HI/LO probe connectors CN40 and CN39.

As shown in FIG. 9, additional circuitry on the LLT card LLT7800 includes switching circuitry 26 for switching between the various outputs and inputs and for simulating various specific fault conditions, depending on the type of LLT test to be run, and a line voltage solid state switch 27 for controlling voltage applied to the DUT. Details of the functions performed by the circuits may be found, by way of example and not limitation, in Associated Research's U.S. Pat. No. 6,011,398.

It is noted that the “CN##” and “SCN##” designations included in the drawings and mentioned above indicate termini of the cables connecting the various boards shown in FIG. 1. Although referred to as connectors, the termini may be in the form of direct solder connections, bus bars, or any other electrical connections. Similar cable terminus identifications are used throughout the drawings but, in the interest of conciseness, not been specifically described. Only those connections directly relevant to the preferred intermediate voltage power supply and/or that are helpful to understanding of the operation of the multiple function tester in which the preferred power supply is included, have been discussed in detail, although those skilled in the art can trace the necessary connections based on the terminal and line numbers shown in the drawings.

Finally, it is noted that because the specific functions of the individual resistors, diodes, op amps, and other illustrated circuit elements are in general apparent from the illustrations and will be readily understood by those skilled in the art, detailed explanations of individual circuit elements have only been given with respect to those elements or combinations of elements that specifically illustrate or implement the principles of the invention and that have functions other than routine bias, filtering, and similar functions.

Having thus described a preferred embodiment of the invention in sufficient detail to enable those skilled in the art to make and use the invention, it will nevertheless be appreciated that numerous variations and modifications of the illustrated embodiment may be made without departing from the spirit of the invention, and it is intended that the invention not be limited by the above description or accompanying drawings, but that it be defined solely in accordance with the appended claims.

What is claimed is:

1. An electrical test instrument arranged to supply intermediate voltage operating currents to a device under test (DOT) for run and/or line leakage testing, comprising:
a line voltage input for inputting a line voltage from a line voltage source;
an output port connected to a socket for receiving a power chord of the DOT and supplying operating current to the DOT; and
an amplifier circuit and an intermediate voltage circuit connected to the line voltage input for converting said line voltage into at least one intermediate voltage,
wherein said intermediate voltage circuit includes a switching circuit connected between said amplifier circuit and said output port for selectively supplying said intermediate voltage and a multiple of said at least one intermediate voltage to said output port.

2. An electrical test instrument as claimed in claim 1, wherein said intermediate voltage is variable from 0 to 150V.

3. An electrical test instrument as claimed in claim 2, wherein said multiple of said intermediate voltage is variable from 0 to 300V.

4. An electrical test instrument as claimed in claim 1, wherein said intermediate voltage circuit further comprises an intermediate voltage transformer connected between said amplifier circuit and said switching circuit, wherein said switching circuit is arranged to switch between parallel and series connections to the secondary windings of the intermediate voltage transformer.

5. An electrical test instrument as claimed in claim 4, wherein said intermediate voltage transformer supplies additional test currents for tests other than run and line leakage tests.

6. An electrical test instrument as claimed in claim 4, further comprising additional transformers connected to said amplifier circuit for generating additional test currents for tests other than run and line leakage tests.

7. An electrical test instrument as claimed in claim 6, wherein said additional transformers include a high voltage transformer for generating high voltage dielectric withstand test currents.

8. An electrical test instrument as claimed in claim 6, wherein said additional transformers include step-down transformers connected to said amplifier circuit for generating low voltage continuity test currents.

9. An electrical test instrument as claimed in claim 1, wherein said amplifier circuit includes a power factor controller.

10. An electrical test instrument as claimed in claim 1, wherein said electrical test instrument is a multiple function electrical test instrument that includes additional test circuitry for generating high voltage, ground bond, and continuity test currents, said additional test circuitry sharing said amplifier circuit with said intermediate voltage circuit.

11. An electrical test instrument as claimed in claim 1, further comprising a line voltage input port for supplying an external line voltage from an external power source, and a internal/external switch for switching between the intermediate voltage and the external line voltage.
